(19) United States
(12) Patent Application Publication
(10) Pub. No.: US 2019/0115947 A1
(43) Pub. Date: Apr. 18, 2019

(54) RADIO-FREQUENCY FRONT END CIRCUIT AND COMMUNICATION APPARATUS

(71) Applicant: Murata Manufacturing Co., Ltd., Kyoto (JP)

(72) Inventor: Koji NOSAKA, Kyoto (JP)

(21) Appl. No.: 16/196,214

(22) Filed: Nov. 20, 2018

Related U.S. Application Data
(63) Continuation of application No. PCT/JP2017/014956, filed on Apr. 12, 2017.

(30) Foreign Application Priority Data
May 20, 2016 (JP) 2016-101992

(51) Int. Cl. H04B 1/44; H03H 9/72; H03F 3/19; H03H 9/64; H04B 1/50

(52) U.S. Cl. CPC H04B 1/44; H03H 9/72; H03F 3/245; H03H 9/6483; H04B 1/50; H03F 3/19

(57) ABSTRACT

A radio-frequency front end circuit includes a filter which includes a first input-output terminal and a second input-output terminal, the first input-output terminal of which is connected to an antenna common terminal, and the frequencies of a pass band of which are varied between a first pass band and a second pass band; a filter which includes a third input-output terminal and a fourth input-output terminal, the third input-output terminal of which is connected to the antenna common terminal, and which has a third pass band the frequencies of which are not overlapped with those of the first pass band and the second pass band; and a switch which includes a common terminal and selection terminals.

This is a continuation of International Application No. PCT/JP2017/014956 filed on Apr. 12, 2017 which claims priority from Japanese Patent Application No. 2016-101992 filed on May 20, 2016. The contents of these applications are incorporated herein by reference in their entireties.

### BACKGROUND

### Technical Field

The present disclosure relates to a radio-frequency front end circuit and a communication apparatus.

Radio-frequency front end circuits that selectively pass radio-frequency signals in multiple frequency bands have hitherto been in practical use in order to support complex mobile communication devices, such as multimode-multiband mobile communication devices.

FIG. 14 is a circuit configuration diagram of a multiband mobile communication terminal capable of carrier aggregation, described in Patent Document 1. The mobile communication terminal described in FIG. 14 includes an antenna 611, a tunable diplexer 600, SPDT switches 612 and 613, duplexers 614, 615A, 615B, and 616, a low noise amplifier 630, a power amplifier 631, a radio-frequency (RF) signal processing circuit 632, and a baseband signal processing circuit 633. The tunable diplexer 600 is composed of an inductor and a variable capacitance element. An arbitrary duplexer is selected and the frequency characteristics of the tunable diplexer 600 are varied with the SPDT switches 612 and 613. With the above configuration, the carrier aggregation of Band21 and Band3 and the carrier aggregation of Band21 and Band19 are capable of being realized.
Patent Document 1: Japanese Unexamined Patent Application Publication No. 2014-225794

### BRIEF SUMMARY

However, it is necessary to dispose a filter or a duplexer for each frequency band that is used in the circuit configuration of the multiband mobile communication terminal disclosed in Patent Document 1. In particular, even when the pass bands of the respective bands have the relationship in which the pass bands of the respective bands are partially overlapped with each other or adjacent to each other, it is necessary to dispose the filter or the duplexer in association with each band. Accordingly, the number of filters or duplexers is increased and, furthermore, the number of terminals of switches used for band switching is increased as the number of bands is increased. Consequently, there is a problem in that the area and the cost of a front end circuit in the mobile communication terminal are increased.

The present disclosure provides a radio-frequency front end circuit and a communication apparatus capable of decreasing the number of filters or duplexers to reduce the size and the cost for a multiband system.

The present disclosure provides a radio-frequency front end circuit that includes an antenna common terminal to be connected to an antenna element and that transmits and receives radio-frequency signals via the antenna element. The radio-frequency front end circuit includes a first filter which includes a first input-output terminal and a second input-output terminal, the first input-output terminal of which is connected to the antenna common terminal, and the frequencies of at least pass band of which are varied between a first pass band and a second pass band; a second filter which includes a third input-output terminal and a fourth input-output terminal, the third input-output terminal of which is connected to the antenna common terminal, and which has a third pass band the frequencies of which are not overlapped with those of the first pass band and the second pass band; and a first switch circuit which includes a first common terminal, a first selection terminal, and a second selection terminal, the first common terminal of which is connected to the second input-output terminal, the first selection terminal of which is connected to one of a transmission-side path and a reception-side path, the second selection terminal of which is connected to the other of the transmission-side path and the reception-side path, and in which connection between the first common terminal and the first selection terminal and connection between the first common terminal and the second selection terminal are exclusively switched.

In related art, even when multiple bands the pass bands of which have the relationship in which the pass bands of the multiple bands are partially overlapped with each other or adjacent to each other in a multiband radio-frequency front end circuit that transmits and receives radio-frequency signals in the multiple frequency bands, it is necessary to dispose a filter or a duplexer in association with each band.

In contrast, with the above configuration, the first filter is capable of being switched between a transmission filter and a reception filter with the first switch circuit. Accordingly, for example, even when the transmission bands and the reception bands of different bands have the relationship in which the transmission bands and the reception bands of different bands are partially overlapped with each other or adjacent to each other, the first filter is capable of serving as both the transmission filter of one band and the reception filter of the other band. Accordingly, the number of filters or duplexers composed of the filters is capable of being decreased in a multiband system. In addition, the number of terminals of the switches used for band switching is capable of being decreased. Consequently, it is possible to reduce the size and the cost of the radio-frequency front end circuit.

The radio-frequency front end circuit may further include a transmission terminal which is connected to the transmission-side path and through which a radio-frequency signal from a subsequent circuit is input; a reception terminal which is connected to the reception-side path and through which a radio-frequency signal is supplied to the subsequent circuit; and a second switch circuit which includes a second common terminal, a third selection terminal, and a fourth selection terminal, the third selection terminal of which is connected to the second selection terminal, the fourth selection terminal of which is connected to the fourth input-output terminal, and the second common terminal of which is connected to one of the reception terminal and the transmission terminal. The first selection terminal may be connected to the other of the reception terminal and the transmission terminal.

With the above configuration, due to the second switch circuit, for example, when the first filter is used as the transmission filter, the second filter is capable of being used as the reception filter. Alternatively, when the first filter is used as the reception filter, the second filter is capable of being used as the transmission filter. Accordingly, the number of filters or duplexers composed of the filters is capable of being decreased in a multiband system. In addition, the number of terminals of the switches used for band switching is capable of being decreased. Consequently, it is possible to reduce the size and the cost of the radio-frequency front end circuit.

The first switch circuit may be composed of a single pole double throw switch.

With the above configuration, even when the number of switch circuits is increased by a number corresponding to the decreased number of filters for a multiband system, the switch circuits have the simplified single pole double throw switch configuration. Accordingly, it is possible to reduce the size and the cost of the entire radio-frequency front end circuit.

The first switch circuit and the second switch circuit may be formed in one package.

With the above configuration, for example, commonly using the second selection terminal and the third selection terminal and forming the two common terminals (the first common terminal and the second common terminal) and the three selection terminals (the first selection terminal to the fourth selection terminal) in one package enables the first switch circuit and the second switch circuit to be integrated with each other. Accordingly, it is possible to reduce the size and the cost of the radio-frequency front end circuit.

The radio-frequency front end circuit may transmit and receive radio-frequency signals in a first band in which the first pass band is used as a transmission band and the third pass band is used as a reception band and in a second band in which the second pass band is used as the reception band and which is exclusively used with the first band. The first pass band and the second pass band may be at least partially overlapped with each other.

With the above configuration, since the first band and the second band are exclusively used, the above configuration is capable of being applied even when the first pass band and the second pass band are partially overlapped with each other.

The radio-frequency front end circuit may transmit and receive radio-frequency signals in the first band, which is Band28b (transmission band: 718 MHz to 748 MHz and reception band: 773 MHz to 803 MHz) in Long Term Evolution standard, in the second band, which is Band29 (reception band: 717.25 MHz to 727.25 MHz) in the Long Term Evolution standard, and in a third band, which is Band28a (transmission band: 703 MHz to 733 MHz and reception band: 758 MHz to 788 MHz) in the Long Term Evolution standard.

Switching the pass band of the first filter between the first pass band and the second pass band enables the first filter to be applied as the Band28a and Band28b transmission filter. In addition, the first filter is capable of being applied as the Band29 reception filter with the first switch circuit. Accordingly, it is possible to configure the compact multiband radio-frequency front end circuit using the above three bands at a low cost.

The radio-frequency front end circuit may transmit and receive radio-frequency signals in the first band, which is Band27 (transmission band: 807 MHz to 824 MHz and reception band: 852 MHz to 869 MHz) in Long Term Evolution standard and in the second band, which is Band20 (transmission band: 832 MHz to 862 MHz and reception band: 791 MHz to 821 MHz) in the Long Term Evolution standard.

Switching the pass band of the first filter between the first pass band and the second pass band enables the first filter to be applied as the Band27 transmission filter and the Band20 reception filter. Accordingly, it is possible to configure the compact multiband radio-frequency front end circuit using the above two bands at a low cost.

The first filter may include a series arm resonator connected between the first input-output terminal and the second input-output terminal; a parallel arm resonator connected between a node on a path connecting the first input-output terminal, the series arm resonator, and the second input-output terminal and a reference terminal; and a switch element that is disposed between the node and the reference terminal and that switches between a conductive state and a non-conductive state of a path connecting the node, the parallel arm resonator, and the reference terminal.

With the above configuration, when the switch element is in the non-conductive state in the bandpass filter circuit composed of the series arm resonator and the parallel arm resonator, first bandpass characteristics are formed with the series arm resonator and the parallel arm resonator. When the switch element is in the conductive state, a different circuit state occur between the node and the reference terminal and, thus, second bandpass characteristics different form the first bandpass characteristics are formed. Accordingly, for example, the band width of the first bandpass characteristics may be made different from the band width of the second bandpass characteristics. In other words, the pass band and the attenuation band of the filter circuit is capable of being adjusted by switching the switch element. In the related art, it is necessary to provide two filter circuits and an SPDT switch for switching between the two filters in a tunable filter circuit applied to a system that exclusively selects two bands that are adjacent to each other. In contrast, with the above configuration, the tunable filter circuit is capable of being composed of one filter circuit and a single pole single throw (SPST) switch element. Accordingly, it is possible to simplify the first variable filter and to reduce the size of the first variable filter.

Each of the first filter and the second filter may be a surface acoustic wave filter, an acoustic wave filter using bulk acoustic waves (BAWs), an LC resonant filter, or a dielectric filter.

With the above configuration, since the sizes of the first filter and the second filter are reduced, it is possible to reduce the size and the cost of the circuit.

The switch element may be a field effect transistor (FET) switch made of gallium arsenide (GaAs) or formed of a complementary metal oxide semiconductor (CMOS) or a diode switch.

With the above configuration, it is possible to reduce the size and the cost of the first filter.

The radio-frequency front end circuit may further include a transmission amplifier circuit that is connected to the transmission-side path and that amplifies a radio-frequency transmission signal; and a reception amplifier circuit that is connected to the reception-side path and that amplifies a radio-frequency reception signal.

With the above configuration, it is possible to reduce the size and the cost of the radio-frequency front end circuit including the amplifier circuits.

The present disclosure provides a communication apparatus including any of the radio-frequency front end circuits described above; a controller that controls a pass band of the first filter and a connection state of the first switch circuit; and a radio-frequency (RF) signal processing circuit that processes a radio-frequency signal. The controller performs switching between the first pass band and the second pass band in conjunction with switching of connection among the first common terminal, the first selection terminal, and the second selection terminal.

With the above configuration, since the controller controls the connection state of the first switch circuit in conjunction with the pass band of the first filter, it is possible to realize the communication apparatus capable of appropriately selecting the multiband filter.

According to the radio-frequency front end circuit according to the present disclosure, since the number of filter or duplexers and the number of terminals of switches for band switching are capable of being decreased in a multiband system, it is possible to reduce the size and the cost of the radio-frequency front end circuit.

### BRIEF DESCRIPTION OF THE SEVERAL VIEWS OF THE DRAWINGS

FIG. 1 is a configuration diagram of a radio-frequency front end circuit according to a first embodiment and circuits around the radio-frequency front end circuit.

FIG. 2 is a diagram for describing frequency allocation in bands used in the radio-frequency front end circuit according to the first embodiment.

FIG. 3 is a circuit configuration diagram of filters composing the radio-frequency front end circuit according to the first embodiment.

FIG. 4 includes an exemplary plan view and an exemplary cross-sectional view schematically illustrating each resonator in the filters according to the first embodiment.

FIG. 5A is a graph indicating filter bandpass characteristics of the radio-frequency front end circuit according to the first embodiment in B28a and B28b transmission.

FIG. 5B is a graph indicating filter bandpass characteristics of the radio-frequency front end circuit according to the first embodiment in B28a, B28b, and B29 reception.

FIG. 6 is a circuit configuration diagram of a radio-frequency front end circuit according to a comparative example.

FIG. 7 is a configuration diagram of a radio-frequency front end circuit according to a first modification of the first embodiment and circuits around the radio-frequency front end circuit.

FIG. 8 is a configuration diagram of a radio-frequency front end circuit according to a second modification of the first embodiment and circuits around the radio-frequency front end circuit.

FIG. 9 is a configuration diagram of a radio-frequency front end circuit according to a third modification of the first embodiment and circuits around the radio-frequency front end circuit.

FIG. 10 is a configuration diagram of a radio-frequency front end circuit according to a fourth modification of the first embodiment and circuits around the radio-frequency front end circuit.

FIG. 11 is a configuration diagram of a radio-frequency front end circuit according to a second embodiment and circuits around the radio-frequency front end circuit.

FIG. 12 is a diagram for describing frequency allocation in bands used in the radio-frequency front end circuit according to the second embodiment.

FIG. 13A is a graph indicating circuit connection of the radio-frequency front end circuit according to the second embodiment in Band27 transmission and reception.

FIG. 13B is a graph indicating circuit connection of the radio-frequency front end circuit according to the second embodiment in Band20 transmission and reception.

FIG. 14 is a circuit configuration diagram of a multiband mobile communication terminal capable of carrier aggregation, described in Patent Document 1.

### DETAILED DESCRIPTION

Embodiments of the present disclosure will herein be described in detail using examples with reference to the drawings. The embodiments described below indicate comprehensive or specific examples. Numerical values, shapes, materials, components, the arrangement of the components, the connection mode of the components, and so on, which are indicated in the embodiments described below, are only examples and are not intended to limit the present disclosure. Among the components in the embodiments described below, the components that are not described in the independent claims are described as optional components. In addition, the sizes or the ratios of the sizes of the components illustrated in the drawings are not necessarily strictly indicated.

### First Embodiment

### [1. 1 Circuit Configuration of Communication Apparatus]

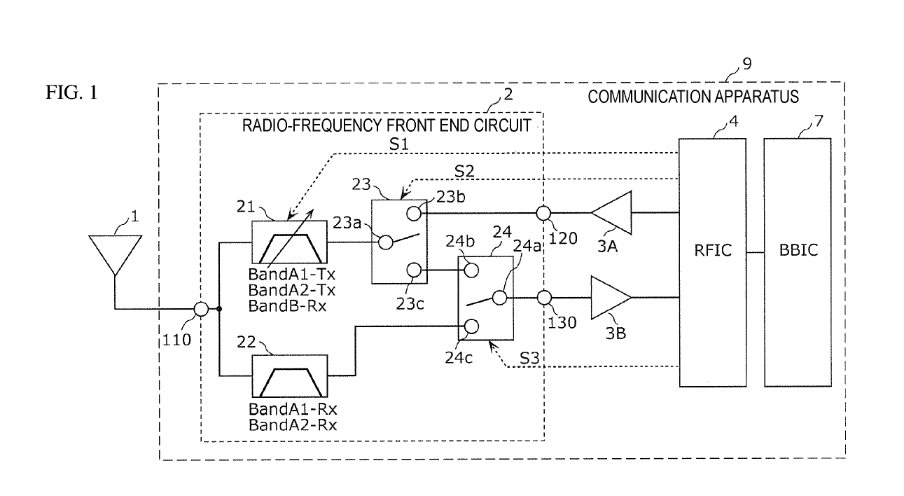

FIG. 1 is a configuration diagram of a radio-frequency front end circuit 2 according to a first embodiment and circuits around the radio-frequency front end circuit 2. An antenna element 1, the radio-frequency front end circuit 2, a transmission amplifier circuit 3A, a reception amplifier circuit 3B, an radio-frequency (RF) signal processing circuit (radio-frequency integrated circuit (RFIC)) 4, and a baseband signal processing circuit (baseband integrated circuit (BBIC)) 7 are illustrated in FIG. 1. The radio-frequency front end circuit 2, the transmission amplifier circuit 3A, the reception amplifier circuit 3B, the RF signal processing circuit (RFIC) 4, and the baseband signal processing circuit (BBIC) 7 compose a communication apparatus 9. The antenna element 1, the radio-frequency front end circuit 2, the transmission amplifier circuit 3A, the reception amplifier circuit 3B, and the RFIC 4 is disposed in, for example, a front end unit in a multimode-multiband cellular phone.

The RFIC 4 performs signal processing, such as down-conversion, to a radio-frequency reception signal input into the RFIC 4 from the antenna element 1 via a reception-side signal path and supplies a reception signal generated through the signal processing to the BBIC 7. In addition, the RFIC 4 performs signal processing, such as up-conversion, to a transmission signal input into the RFIC 4 from the BBIC 7 and supplies a radio-frequency transmission signal generated through the signal processing to the transmission amplifier circuit 3A.

Furthermore, the RFIC 4 functions as a controller that controls a conductive state and a non-conductive state of each switch in the radio-frequency front end circuit 2 based on a frequency band that is used.

The BBIC 7 is a circuit that performs signal processing using an intermediate frequency band lower than the radio-frequency signals used in the front end unit. An image signal processed in the BBIC 7 is used for, for example, display of an image and an audio signal processed in the BBIC 7 is used for, for example, a call using a speaker.

The transmission amplifier circuit 3A performs power amplification of the radio-frequency transmission signal supplied from the RFIC 4 and supplies the amplified radio-frequency transmission signal to a transmission terminal 120 of the radio-frequency front end circuit 2.

The reception amplifier circuit 3B amplifies the radio-frequency reception signal supplied through a reception terminal 130 of the radio-frequency front end circuit 2 and supplies the amplified radio-frequency reception signal to the RFIC 4. The transmission amplifier circuit 3A, the reception amplifier circuit 3B, and the RFIC 4 correspond to subsequent circuits of the radio-frequency front end circuit 2.

The configuration is adopted in the present embodiment in which the transmission amplifier circuit 3A and the reception amplifier circuit 3B are disposed, separately from the radio-frequency front end circuit 2, a configuration may be adopted in which the radio-frequency front end circuit 2 includes the transmission amplifier circuit 3A and the reception amplifier circuit 3B.

### [1. 2 Configuration of Radio-Frequency Front End Circuit]

The radio-frequency front end circuit 2 includes filters 21 and 22, switches 23 and 24, an antenna common terminal 110, the transmission terminal 120, and the reception terminal 130. With this configuration, the radio-frequency front end circuit 2 transmits and receives radio-frequency signals in BandA1, BandA2, and BandB via the antenna element 1.

The filter 21 is a first filter which includes a first input-output terminal (not illustrated) connected to the antenna common terminal 110 and a second input-output terminal (not illustrated) connected to the switch 23 and the frequencies of the pass band of which are varied between a first pass band and a second pass band. The first pass band corresponds to a transmission band of BandA2 (a first band), and the second pass band corresponds to a transmission band of BandA1 (a third band) and a reception band of BandB (a second band).

The filter 22 is a second filter that includes a third input-output terminal (not illustrated) connected to the antenna common terminal 110 and a fourth input-output terminal (not illustrated) connected to the switch 24 and that has a third pass band the frequencies of which are not overlapped with those of the first pass band and the second pass band. The third pass band corresponds to a reception band of BandA1 and BandA2.

The filter 21 and the filter 22 compose a duplexer corresponding to both BandA1 and BandA2.

The switch 23 is a single pole double throw (SPDT) first switch circuit which includes a common terminal 23a (a first common terminal), a selection terminal 23b (a first selection terminal), and a selection terminal 23c (a second selection terminal) and in which connection between the common terminal 23a and the selection terminal 23b and connection between the common terminal 23a and the selection terminal 23c are exclusively switched in response to a control signal S2 from the RFIC 4. The common terminal 23a is connected to the second input-output terminal of the filter 21. The selection terminal 23b is connected to a transmission-side path including the transmission terminal 120 and the transmission amplifier circuit 3A. The selection terminal 23c is connected to a reception-side path including the switch 24, the reception terminal 130, and the reception amplifier circuit 3B.

With the above configuration, the filter 21 is capable of being used while the variable pass band of the filter 21 is switched between the transmission band of BandA1 and BandA2 and the reception band of BandB with the switch 23. In other words, the filter 21 serves as both a transmission filter of one band and a reception filter of the other band. Accordingly, the number of filters or duplexers composed of the filters is capable of being decreased in a multiband system.

The switch 24 is a single pole double throw (SPDT) second switch circuit which includes a common terminal 24a (a second common terminal), a selection terminal 24b (a third selection terminal), and a selection terminal 24c (a fourth selection terminal) and in which connection between the common terminal 24a and the selection terminal 24b and connection between the common terminal 24a and the selection terminal 24c are exclusively switched in response to a control signal S3 from the RFIC 4. The selection terminal 24b is connected to the selection terminal 23c. The selection terminal 24c is connected to the fourth input-output terminal of the filter 22. The common terminal 24a is connected to the reception-side path including the reception terminal 130 and the reception amplifier circuit 3B.

Due to the disposition of the switch 24, for example, when the filter 21 is used as the transmission filter of BandA1 and BandA2, the filter 22 is capable of being used as the reception filter of BandA1 and BandA2. Alternatively, when BandA1 and BandA2 are not used, the filter 21 is capable of being used as the reception filter of BandB. Accordingly, the number of filters or duplexers composed of the filters is capable of being decreased in a multiband system.

A case will now be described in which the radio-frequency front end circuit 2 is applied to a multiband system using Band28a, Band28b, and Band29 in Long Term Evolution (LTE) standard.

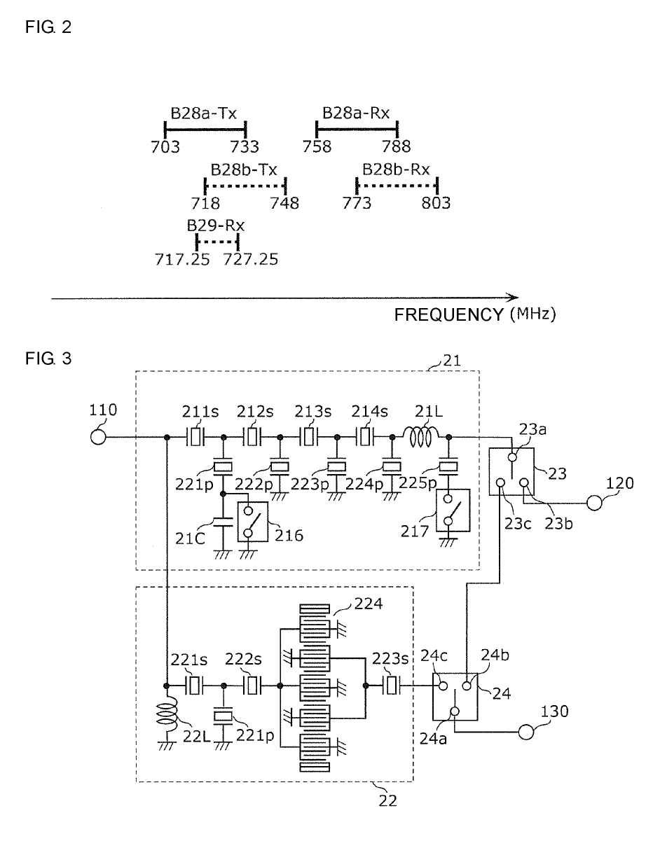

FIG. 2 is a diagram for describing frequency allocation in the bands used in the radio-frequency front end circuit 2 according to the first embodiment. The frequency allocation of Band28a, Band28b, and Band29 is illustrated in FIG. 2. The transmission band of Band28a (703 MHz to 733 MHz), the transmission band of Band28b (718 MHz to 748 MHz), and the reception band of Band29 (717.25 MHz to 727.25 MHz) are partially overlapped with each other. The reception band of Band28a (758 MHz to 788 MHz) and the reception band of Band28b (773 MHz to 803 MHz) are partially overlapped with each other. Band28a, Band28b, and Band29 are not simultaneously used but exclusively used.

In a multiband system using the above three bands, the variable pass band of the filter 21 is associated with the transmission band of Band28a (the third band), the transmission band of Band28b (the first band), and the reception band of Band29 (the second band), the frequency bands of which are partially overlapped with each other. The pass band of the filter 22 is associated with the reception band of Band28a and the reception band of Band28b.

Accordingly, in the radio-frequency front end circuit 2, the common terminal 23a of the switch 23 is connected downstream of the tunable filter 21 having the variable pass band and attenuation band, as illustrated in FIG. 1, to switch between the transmission band of Band28a/28b and the reception band of Band29. Consequently, the radio-frequency front end circuit 2 composes a duplexer circuit supporting the three bands, in which the filter 21 and the filter 22 are connected to the antenna common terminal 110. The frequency band of the filter 21 is varied between the transmission band of Band28a/Band28b and the reception band of Band29. The frequency band of the filter 22 is fixed and covers the reception band of Band28a/28b. A specific circuit configuration of the filters 21 and 22 will now be described.

FIG. 3 is a circuit configuration diagram of the filters 21 and 22 composing the radio-frequency front end circuit 2 according to the first embodiment.

The filter 21 includes series arm resonators 211s, 212s, 213s, and 214s, parallel arm resonators 221p, 222p, 223p, 224p, and 225p, a capacitor 21C, an inductor 21L, and switches 216 and 217.

The series arm resonators 211s to 214s are connected in series between the first input-output terminal (not illustrated) connected to the antenna common terminal 110 and the second input-output terminal (not illustrated) connected to the common terminal 23a.

The parallel arm resonators 221p to 225p are connected in parallel between nodes on a path connecting the first input-output terminal, the series arm resonators 211s to 214s, and the second input-output terminal and a ground (reference) terminal.

The capacitor 21C and the switch 216 are connected in parallel between the parallel arm resonator 221p and the ground (reference) terminal. The inductor 21L is connected between the series arm resonator 214s and the second input-output terminal. The switch 217 is connected between the parallel arm resonator 225p and the ground (reference) terminal.

With the above configuration, the filter 21 composes a ladder band pass filter.

Here, individual switching between turning-on and turning-off of the switch 216 and between turning-on and turning-off of the switch 217 enables the sharpness of attenuation characteristics at the lower frequency side of the ladder resonant circuit to be adjusted.

Each of the switches 216 and 217 is, for example, a field effect transistor (FET) switch made of gallium arsenide (GaAs) or formed of a complementary metal oxide semiconductor (CMOS) or a diode switch. Since each of the switches 216 and 217 is capable of being composed of one FET switch or one diode switch, it is possible to realize the compact filter 21.

The filter 22 includes a longitudinally coupled resonator type filter unit 224, series arm resonators 221s, 222s, and 223s, a parallel arm resonator 221p, and an inductor 22L.

In the present embodiment, each resonator composing the filters 21 and 22 is a resonator using surface acoustic waves. Accordingly, since the filters 21 and 22 are capable of being composed of interdigital transducer (IDT) electrodes formed on a piezoelectric substrate, it is possible to realize a compact and low-profile filter circuit having sharp bandpass characteristics. The structure of a surface acoustic wave resonator will now be described.

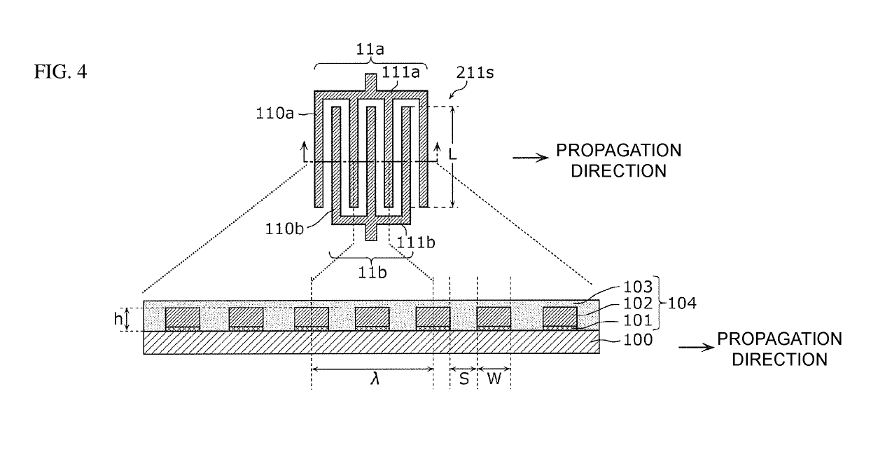

FIG. 4 includes an exemplary plan view and an exemplary cross-sectional view schematically illustrating each resonator in the filters 21 and 22 according to the first embodiment. A schematic plan view and a schematic cross-sectional view illustrating the structure of the series arm resonator 221s, among the resonators composing the filters 21 and 22, are exemplified in FIG. 4. The series arm resonator illustrated in FIG. 4 is for describing the typical structure of the multiple resonators and, for example, the number of electrode fingers composing the electrodes and the lengths the electrode fingers are not limited to the ones illustrated in FIG. 4.

Each resonator in the filters 21 and 22 is composed of a piezoelectric substrate 100 and comb-shaped IDT electrodes 11a and 11b.

As illustrated in the plan view in FIG. 4, the pair of IDT electrodes 11a and 11b, which are opposed to each other, is formed on the piezoelectric substrate 100. The IDT electrode 11a is composed of multiple electrode fingers 110a, which are parallel to each other, and a busbar electrode 111a with which the multiple electrode fingers 110a are connected. The IDT electrode 11b is composed of multiple electrode fingers 110b, which are parallel to each other, and a busbar electrode 111b with which the multiple electrode fingers 110b are connected. The multiple electrode fingers 110a and 110b are formed in a direction orthogonal to a propagation direction.

An IDT electrode 104 composed of the multiple electrode fingers 110a and 110b and the busbar electrodes 111a and 111b has a layered structure including a close contact layer 101 and a main electrode layer 102, as illustrated in the cross-sectional view in FIG. 4.

The close contact layer 101 is a layer for improving the close contact between the piezoelectric substrate 100 and the main electrode layer 102. The close contact layer 101 is made of, for example, Ti. The film thickness of the close contact layer 101 is, for example, 12 nm.

The main electrode layer 102 is made of, for example, Al containing 1% of Cu. The film thickness of the main electrode layer 102 is, for example, 162 nm.

A protective layer 103 is formed so as to cover the IDT electrodes 11a and 11b. The protective layer 103 is a layer intended to, for example, protect the main electrode layer 102 from the external environment, adjust frequency temperature characteristics, and improve moisture resistance. For example, the protective layer 103 is a film containing silicon dioxide as the major component.

The materials of the close contact layer 101, the main electrode layer 102, and the protective layer 103 are not limited to the ones described above. In addition, the IDT electrode 104 may not have the above layered structure. The IDT electrode 104 may be made of metal, such as Ti, Al, Cu, Pt, Au, Ag, or Pd, or alloy containing two or more of the above elements. The IDT electrode 104 may be composed of multiple multilayer bodies made of the above metal or alloy. The protective layer 103 may not be formed.

The piezoelectric substrate 100 is made of, for example, LiTaO₃ piezoelectric single crystal, LiNbTaO₃ piezoelectric single crystal, or piezoelectric ceramics.

The structure of each resonator in the filters 21 and 22 is not limited to the structure illustrated in FIG. 4. For example, the IDT electrode 104 may not have the layered structure of metal films and may have a single layer of a metal film.

Each resonator in the filters 21 and 22 may not be the surface acoustic wave resonator and may be a resonator using bulk acoustic waves (BAWs). Each of the filters 21 and 22 may be an LC resonant filter or a dielectric filter.

With the above structure, since the sizes of the filters 21 and 22 are capable of being reduced, it is possible to reduce the size and the cost of the circuit.

As described above, the filter 21 according to the present embodiment has the configuration based on the ladder filter using the SAW resonators. The filter 21 is a tunable filter in which the parallel arm resonators 221p and 225p and the capacitor 21C are switched with the switches 216 and 217 to vary filter characteristics. The filter 22 is a filter in which the ladder filter circuit is connected to the longitudinally coupled resonator and the frequency band of which is fixed. The circuit configurations of the filters 21 and 22 according to the present disclosure are not limited to the above circuit configurations. For example, the filter 22 the filter characteristics of which are fixed may be composed of only a ladder filter circuit. The filter 22 may be a tunable filter circuit. The configuration in which the capacitor 21C and the parallel arm resonator 225p are controlled with the switches 216 and 217, which is the circuit configuration of the filter 21 the pass band and the attenuation band of which are varied, is only an example and the circuit configuration of the filter 21 is not limited to the above configuration.

### [1. 3 Circuit Operation of the Radio-Frequency Front End Circuit]

A circuit operation of the radio-frequency front end circuit 2 will now be described.

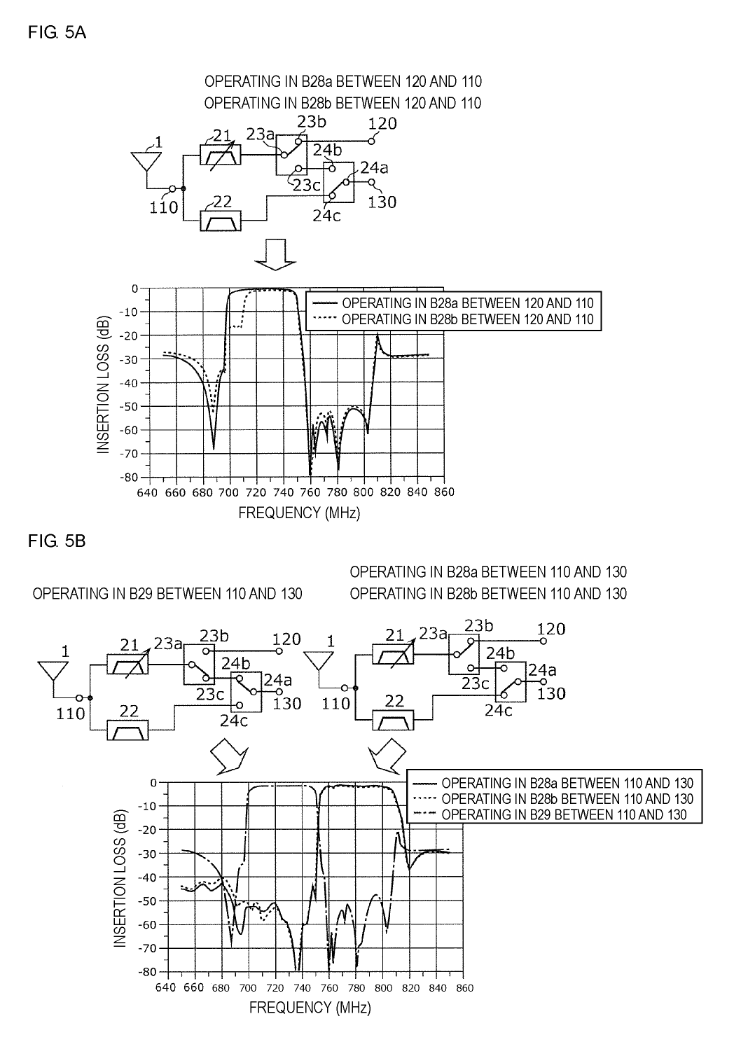

FIG. 5A is a graph indicating filter bandpass characteristics of the radio-frequency front end circuit 2 according to the first embodiment in B28a and B28b transmission. FIG. 5B is a graph indicating filter bandpass characteristics of the radio-frequency front end circuit 2 according to the first embodiment in B28a, B28b, and B29 reception.

First, in a mode in which Band28a/28b are used, the radio-frequency front end circuit 2 has a circuit connection configuration illustrated in an upper part of FIG. 5A and an upper right part of FIG. 5B. Specifically, the common terminal 23a of the switch 23 is connected to the selection terminal 23b thereof in response to the control signal S2 from the RFIC 4, and the common terminal 24a of the switch 24 is connected to the selection terminal 24c thereof in response to the control signal S3 from the RFIC 4. In other words, the filter 21 is connected to the transmission terminal 120 via the switch 23 and functions as a Band28a/28b transmission filter. In contrast, the filter 22 is connected to the reception terminal 130 via the switch 24 and functions as a Band28a/28b reception filter.

In addition, when Band28a is used in the mode in which Band28a/28b are used, the switch 216 in the filter 21 is in an on-state and the switch 217 therein is in an off-state in response to a control signal S1 from the RFIC 4. Here, the filter 21 has bandpass characteristics illustrated in a graph (solid line) in a lower part of FIG. 5A. Specifically, in the passband characteristics between the transmission terminal 120 and the antenna common terminal 110, the transmission band (703 MHz to 733 MHz) of Band28a is used as the pass band, and the reception band (758 MHz to 788 MHz) of Band28a and a digital television (DTV) band (450 MHz to 698 MHz) are used as the attenuation bands. In contrast, the filter 22 has passband characteristics illustrated in a graph (solid line) in a lower part of FIG. 5B. Specifically, in the passband characteristics between the antenna common terminal 110 and the reception terminal 130, the reception band (758 MHz to 788 MHz) of Band28a and the reception band (773 MHz to 803 MHz) of Band28b are used as the pass band, and the transmission band (703 MHz to 748 MHz) of Band28a/28b is used as the attenuation band.

Furthermore, when Band28b is used in the mode in which Band28a/28b are used, the switch 216 in the filter 21 is in the off-state and the switch 217 therein is in the on-state in response to the control signal S1 from the RFIC 4. Here, the filter 21 has bandpass characteristics illustrated in a graph (broken line) in the lower part of FIG. 5A. Specifically, in the passband characteristics between the transmission terminal 120 and the antenna common terminal 110, the transmission band (718 MHz to 748 MHz) of Band28b is used as the pass band, and the reception band (773 MHz to 803 MHz) of Band28b and a DTV band (450 MHz to 710 MHz) are used as the attenuation bands. In contrast, the filter 22 has passband characteristics illustrated in a graph (broken line) in the lower part of FIG. 5B. Specifically, in the passband characteristics between the antenna common terminal 110 and the reception terminal 130, the reception band (758 MHz to 788 MHz) of Band28a and the reception band (773 MHz to 803 MHz) of Band28b are used as the pass band, and the transmission band (703 MHz to 748 MHz) of Band28a/28b is used as the attenuation band.

Next, in a mode in which Band29 is used, the radio-frequency front end circuit 2 has a circuit connection configuration illustrated in an upper left part of FIG. 5B. Specifically, the common terminal 23a of the switch 23 is connected to the selection terminal 23c thereof in response to the control signal S2 from the RFIC 4, and the common terminal 24a of the switch 24 is connected to the selection terminal 24b thereof in response to the control signal S3 from the RFIC 4. In other words, the filter 21 is connected to the reception terminal 130 via the switches 23 and 24 and functions as a Band29 reception filter. In contrast, the filter 22 is connected to none of the transmission terminal 120 and the reception terminal 130.

In addition, when Band29 is used, the switch 216 in the filter 21 is in the on-state and the switch 217 therein is in the off-state in response to the control signal S1 from the RFIC 4. Here, the filter 21 has bandpass characteristics illustrated in a graph (alternate long and short dash line) in the lower part of FIG. 5B. Specifically, in the passband characteristics between the antenna common terminal 110 and the reception terminal 130, the reception band (717.25 MHz to 727.25 MHz) of Band29 is used as the pass band.

As described above, varying the pass band of the filter 21 enables the filter 21 to be applied to the Band28a and Band28b transmission filter. In addition, the filter 21 is capable of being applied to the Band29 reception filter using the switches 23 and 24. Accordingly, it is possible to configure the compact multiband radio-frequency front end circuit using the above three bands at a low cost.

The controller of the RFIC 4 controls the connection state between the switches 23 and 24 in conjunction with the pass band of the filter 21 by supplying the control signals S1 to S3. Accordingly, it is possible to realize the communication apparatus capable of appropriately selecting the multiband filter or duplexer.

The controller may not be built in the RFIC 4 and the radio-frequency front end circuit 2 may include the controller.

[1. 4 Comparison with Related Art]

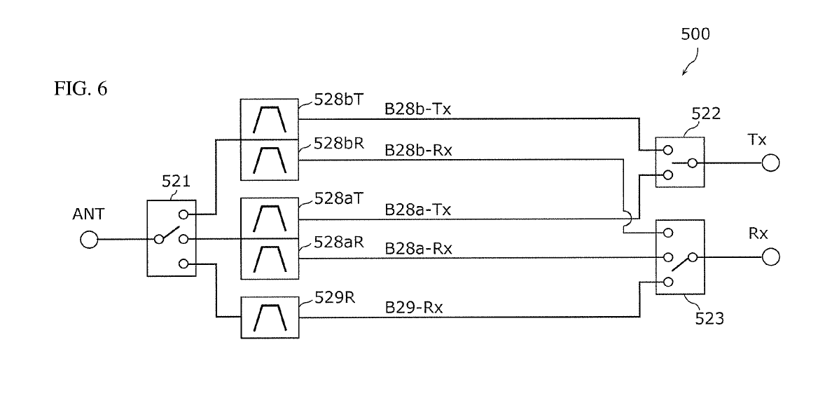

FIG. 6 is a circuit configuration diagram of a radio-frequency front end circuit 500 according to a comparative example. The circuit configuration in the related art of the radio-frequency front end circuit 500 when the radio-frequency front end circuit 500 is applied to a multiband system using Band28a, Band28b, and Band 29 in the LTE standard is illustrated in FIG. 6. The radio-frequency front end circuit 500 includes an SP3T switch 521, filters 528bT, 528bR, 528aT, 528aR, and 529R, an SPDT switch 522, an SP3T switch 523, an antenna common terminal ANT, a transmission terminal Tx, and a reception terminal Rx. The radio-frequency front end circuit 500 transmits and receives radio-frequency signals in Band28a, Band28b, and Band29 via the antenna element in this configuration.

In the radio-frequency front end circuit 500 according to the comparative example, the filters 528bT, 528bR, 528aT, 528aR, and 529R are disposed in association with Band28b transmission, Band28b reception, Band28a transmission, Band28a reception, and Band29 reception. In addition, the SP3T switch 521 for switching between Band28a, Band28b, and Band29, the SPDT switch 522 for switching between the transmission paths of Band28a and Band28b, and the SP3T switch 523 for switching between the reception paths of Band28a, Band28b, and Band29 are required.

In other words, in the radio-frequency front end circuit 500 according to the comparative example, it is necessary to dispose the filter or the duplexer for each band that is used. In particular, even when the pass bands of the respective bands have the relationship in which the pass bands of the respective bands are partially overlapped with each other or adjacent to each other, it is necessary to dispose the filter or the duplexer in association with each band. Accordingly, the number of filters or duplexers is increased and, furthermore, the number of terminals of the switches used for band switching is increased as the number of bands is increased. Consequently, there is a problem in that the area and the cost of the front end circuit in the mobile communication terminal are increased.

In contrast, with the radio-frequency front end circuit 2 according to the present embodiment, the filter 21 having the variable pass band is capable of being switched between the transmission filter and the reception filter with the SPDT switch 23. Accordingly, for example, even when the transmission bands and the reception bands of different bands have the relationship in which the transmission bands and the reception bands of different bands are partially overlapped with each other or adjacent to each other, the filter 21 is capable of serving as both the transmission filter of one band and the reception filter of the other band. In the present embodiment, the two filters 21 and 22 compose the Band28a duplexer, the Band28b duplexer, and the Band29 reception filter.

With the above configuration, the number of filters or duplexers composed of the filters is capable of being decreased in a multiband system. In addition, the number of terminals of the switches used for band switching is capable of being decreased. Accordingly, it is possible to reduce the size and the cost of the radio-frequency front end circuit.

### [1. 5 Configuration of Radio-Frequency Front End Circuit According to First Modification]

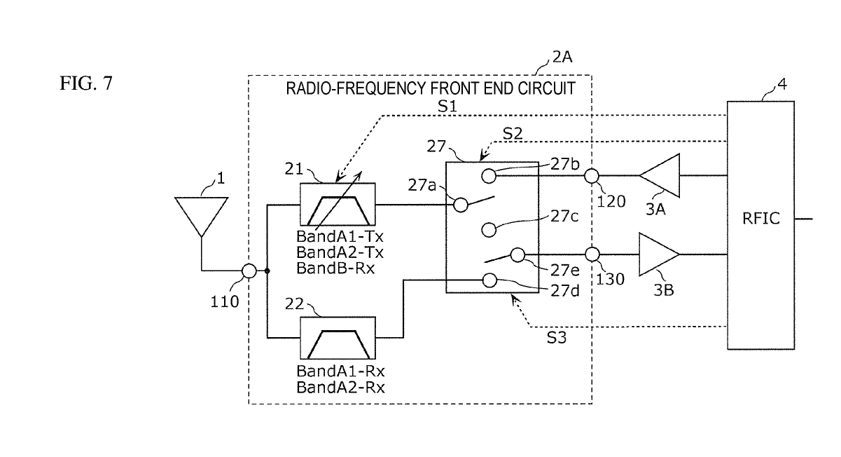

FIG. 7 is a configuration diagram of a radio-frequency front end circuit 2A according to a first modification of the first embodiment and circuits around the radio-frequency front end circuit 2A. As illustrated in FIG. 7, the radio-frequency front end circuit 2A according to the first modification differs from the radio-frequency front end circuit 2 according to the first embodiment in the configuration of a switch disposed downstream of the filters 21 and 22. A description of the same points as in the radio-frequency front end circuit 2 according to the first embodiment is omitted herein and points different from those in the radio-frequency front end circuit 2 according to the first embodiment will be mainly described.

The radio-frequency front end circuit 2A includes the filters 21 and 22, a switch 27, the antenna common terminal 110, the transmission terminal 120, and the reception terminal 130. With this configuration, the radio-frequency front end circuit 2A transmits and receives radio-frequency signals in BandA1, BandA2, and BandB via the antenna element 1.

The switch 27 is a double pole three throw (DP3T) switch circuit which includes a common terminal 27a (the first common terminal), a common terminal 27e (the second common terminal), a selection terminal 27b (the first selection terminal), a selection terminal 27c (the second selection terminal and the third selection terminal), and a selection terminal 27d (the fourth selection terminal) and in which connection between the common terminal 27a and the selection terminal 27b and connection between the common terminal 27a and the selection terminal 27c are exclusively switched in response to the control signal S2 from the RFIC 4 and connection between the communication 27e and the selection terminal 27c and connection between the communication 27e and the selection terminal 27d are exclusively switched in response to the control signal S3 from the RFIC 4. The common terminal 27a is connected to the second input-output terminal of the filter 21. The selection terminal 27b is connected to the transmission-side path including the transmission terminal 120 and the transmission amplifier circuit 3A. The selection terminal 27c is exclusively connected to the common terminal 27a or 27e. The selection terminal 27d is connected to the fourth input-output terminal of the filter 22 via the reception-side path. The communication 27e is connected to the reception-side path including the reception terminal 130 and the reception amplifier circuit 3B.

In other words, the switch 27 is one package in which the switches 23 and 24 in the radio-frequency front end circuit 2 according to the first embodiment are formed and the selection terminal 23c of the switch 23 and the selection terminal 24b of the switch 24 are commonly used. Accordingly, it is possible to reduce the size and the cost of the radio-frequency front end circuit.

### [1. 6 Configuration of Radio-Frequency Front End Circuit According to Second Modification]

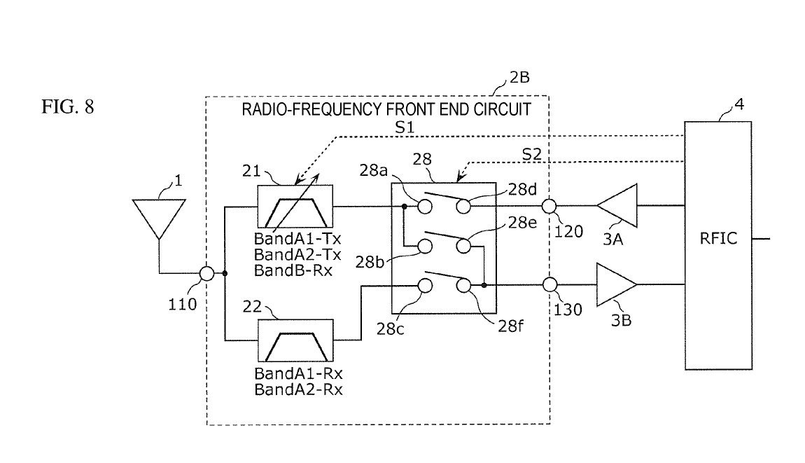

FIG. 8 is a configuration diagram of a radio-frequency front end circuit 2B according to a second modification of the first embodiment and circuits around the radio-frequency front end circuit 2B. As illustrated in FIG. 8, the radio-frequency front end circuit 2B according to the second modification differs from the radio-frequency front end circuit 2 according to the first embodiment in the configuration of a switch disposed downstream of the filters 21 and 22. A description of the same points as in the radio-frequency front end circuit 2 according to the first embodiment is omitted herein and points different from those in the radio-frequency front end circuit 2 according to the first embodiment will be mainly described.

The radio-frequency front end circuit 2B includes the filters 21 and 22, a switch 28, the antenna common terminal 110, the transmission terminal 120, and the reception terminal 130. With this configuration, the radio-frequency front end circuit 2B transmits and receives radio-frequency signals in BandA1, BandA2, and BandB via the antenna element 1.

The switch 28 is a switch circuit which includes a common terminal 28a (the first common terminal), a common terminal 28b (the first common terminal and the third selection terminal), a common terminal 28e (the second common terminal and the second selection terminal), a common terminal 28f (the second common terminal), a selection terminal 28c (the fourth selection terminal), and a selection terminal 28d (the first selection terminal) and in which switching between connection between the common terminal 28a and the selection terminal 28d, connection between the common terminal 28b and the common terminal 28e, and connection between the common terminal 28f and the selection terminal 28c is performed in response to the control signal S2 from the RFIC 4. The common terminals 28a and 28b are short-circuited to each other in the switch circuit, and the common terminals 28e and 28f are short-circuited to each other in the switch circuit. The common terminals 28a and 28b are connected to the second input-output terminal of the filter 21. The selection terminal 28d is connected to the transmission-side path including the transmission terminal 120 and the transmission amplifier circuit 3A. The selection terminal 28c is connected to the fourth input-output terminal of the filter 22 via the reception-side path. The common terminals 28e and 28f are connected to the reception-side path including the reception terminal 130 and the reception amplifier circuit 3B.

The switch 28 according to the present modification does not have the configuration in which connections between the common terminal and the two selection terminals are switched but has a configuration in which the conductive state and the non-conductive state of the respective pairs of terminals are switched in the three pairs of two terminals.

For example, when BandA1 or BandA2 is used, the common terminal 28a is connected to the selection terminal 28d, the common terminal 28b is not connected to the common terminal 28e, and the common terminal 28f is connected to the selection terminal 28c in response to the control signal S2. When BandB is used, the common terminal 28a is not connected to the selection terminal 28d, the common terminal 28b is connected to the common terminal 28e, and the common terminal 28f is not connected to the selection terminal 28c in response to the control signal S2.

Also in the present modification, the switch 28 includes the first common terminals (the common terminals 28a and 28b), the first selection terminal (the selection terminal 28d), and the second selection terminal (the common terminal 28e). The first common terminals (the common terminals 28a and 28b) are connected to the second input-output terminal, the first selection terminal (the selection terminal 28d) is connected to one of the transmission-side path and the reception-side path, and the second selection terminal (the common terminal 28e) is connected to the other of the transmission-side path and the reception-side path.

In addition, the switch 28 includes the second common terminals (the common terminals 28f and 28e), the third selection terminal (the common terminal 28b), and the fourth selection terminal (the selection terminal 28c). The third selection terminal (the common terminal 28b) is connected to the second selection terminal (the common terminal 28e), the fourth selection terminal (the selection terminal 28c) is connected to the fourth input-output terminal, and the second common terminals (the common terminals 28f and 28e) are connected to one of the reception terminal and the transmission terminal.

In other words, the switch 28 is one package in which the switches 23 and 24 in the radio-frequency front end circuit 2 according to the first embodiment are formed. Accordingly, it is possible to reduce the size and the cost of the radio-frequency front end circuit.

### [1. 7 Configuration of Radio-Frequency Front End Circuit According to Third Modification]

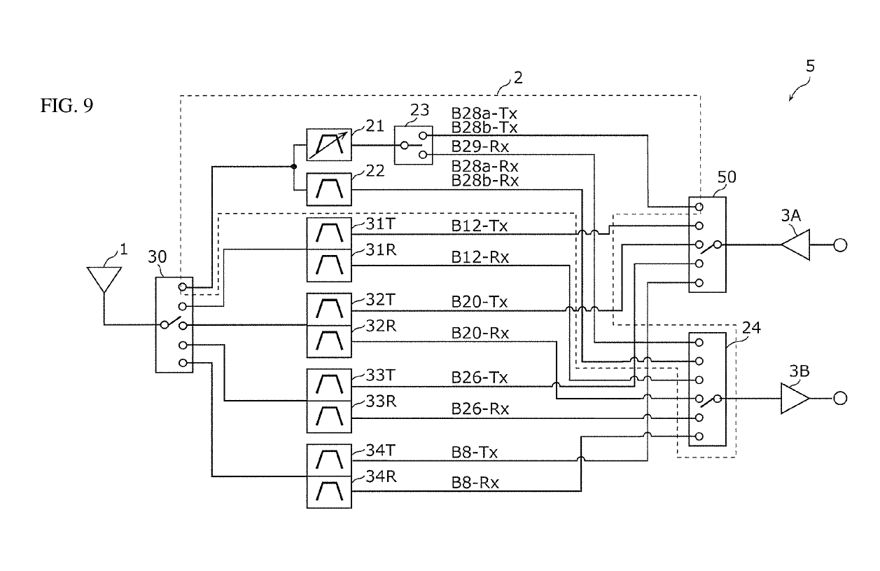

FIG. 9 is a configuration diagram of a radio-frequency front end circuit 5 according to a third modification of the first embodiment and circuits around the radio-frequency front end circuit 5. The radio-frequency front end circuit 5 according to the present modification differs from the radio-frequency front end circuit 2 according to the first embodiment in that the radio-frequency front end circuit 5 according to the present modification is used for a system using a larger number of bands, compared with that in the radio-frequency front end circuit 2 according to the first embodiment. A description of the same points as in the radio-frequency front end circuit 2 according to the first embodiment is omitted herein and points different from those in the radio-frequency front end circuit 2 according to the first embodiment will be mainly described.

As illustrated in FIG. 9, the radio-frequency front end circuit 5 further includes SPST type switches 30 and 50, filters 31T and 31R composing a duplexer of Band12, filters 32T and 32R composing a duplexer of Band20, filters 33T and 33R composing a duplexer of Band26, and filters 34T and 34R composing a duplexer of Band8, in addition to the components in the radio-frequency front end circuit 2 according to the first embodiment. The switch 24 is of the SPDT type in the first embodiment while the switch 24 is of an SP6T type in the present modification.

The switch 30 is provided upstream of the duplexers of the respective bands, includes one common terminal and five selection terminals, and selects one of Band28a/28b/29, Band12, Band20, Band26, and Band8 to connect the selected band to the antenna element 1.

The switch 50 is provided downstream of the transmission filters of the respective bands, includes one common terminal and five selection terminals, and selects one of the filter 21 via the selection terminal 23b of the switch 23, the filter 31T, the filter 32T, the filter 33T, and the filter 34T to connect the selected filter to the transmission amplifier circuit 3A.

The switch 24 is provided downstream of the reception filters of the respective bands, includes one common terminal and six selection terminals, and selects one of the filter 21 via the selection terminal 23c of the switch 23, the filter 22, the filter 31R, the filter 32R, the filter 33R, and the filter 34R to connect the selected filter to the reception amplifier circuit 3B.

As described above, the radio-frequency front end circuit 5 has a multiband configuration using the seven bands.

With the radio-frequency front end circuit 5 according to the present modification, the filter 21 having the variable pass band is capable of being switched between the transmission filter and the reception filter with the SPDT type switch 23 on the signal paths of Band28a/28b/29. In other words, the two filters 21 and 22 compose the duplexer of Band28a, the duplexer of Band28b, and the reception filter of Band29.

Accordingly, the number of filters or duplexers composed of the filters is capable of being decreased also in a multiband system to which bands other than Band28a/28b/29 are added. In addition, the number of terminals of the switches used for band switching is capable of being decreased. Accordingly, it is possible to reduce the size and the cost of the radio-frequency front end circuit.

### [1. 8 Configuration of Radio-Frequency Front End Circuit According to Fourth Modification]

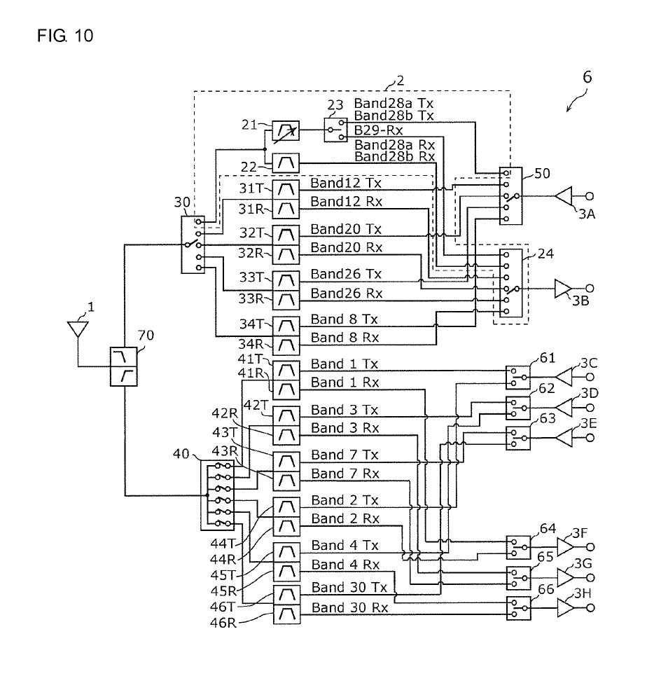

FIG. 10 is a configuration diagram of a radio-frequency front end circuit 6 according to a fourth modification of the first embodiment and circuits around the radio-frequency front end circuit 6. The radio-frequency front end circuit 6 according to the present modification differs from the radio-frequency front end circuit 5 according to the third modification in that the radio-frequency front end circuit 6 supports carrier aggregation. A description of the same points as in the radio-frequency front end circuit 5 according to the third modification is omitted herein and points different from those in the radio-frequency front end circuit 5 according to the third modification will be mainly described.

As illustrated in FIG. 10, the radio-frequency front end circuit 6 further includes a demultiplexer 70 and a high-band circuit, in addition to the radio-frequency front end circuit 5 (low-band circuit) according to the third modification. The high-band circuit includes a switch 40, duplexers supporting Band1, Band3, Band1, Band2, Band4, and Band30, respectively, a switch 61 used to select either of a filter 41T (Band1) and a filter 44T (Band2), a switch 62 used to select either of a filter 42T (Band3) and a filter 45T (Band4), a switch 63 used to select either of a filter 43T (Band7) and a filter 46T (Band30), a switch 64 used to select either of a filter 41R (Band1) and a filter 44R (Band2), a switch 65 used to select either of a filter 42R (Band3) and a filter 45R (Band4), a switch 66 used to select either of a filter 43R (Band7) and a filter 46R (Band30), a transmission amplifier circuit 3C connected to the switch 61, a transmission amplifier circuit 3D connected to the switch 62, a transmission amplifier circuit 3E connected to the switch 63, a reception amplifier circuit 3F connected to the switch 64, a reception amplifier circuit 3G connected to the switch 65, and a reception amplifier circuit 3H connected to the switch 66.

The demultiplexer 70 is composed of a high pass filter and a low pass filter and demultiplexes an input signal into a low-frequency signal at the low band side and a radio-frequency signal at the high band side.

The switch 40 is provided between the respective duplexers composing the high-band circuit and the demultiplexer 70 and includes six switch elements that are parallel to each other. The respective duplexers of Band1, Band3, Band7, Band2, Band4, and Band30 are connected to the antenna element 1 with the switch 40. In the configuration of the switch 40, an arbitrary number of bands may be connected to the antenna element 1 in the high-band circuit. However, due to the configuration of the switches 61 to 66, Band1 and Band2 are exclusively selected, Band3 and Band4 are exclusively selected, and Band1 and Band30 are exclusively selected.

With the above configuration, the radio-frequency front end circuit 6 is capable of performing the carrier aggregation in which one band selected from the low-band circuit and one or more bands selected from the high-band circuit are simultaneously used.

Accordingly, the number of filters or duplexers composed of the filters is capable of being decreased also in a multiband system to which bands other than Band28a/28b/29 are added and in which the carrier aggregation is enabled. In addition, the number of terminals of the switches used for band switching is capable of being decreased. Accordingly, it is possible to reduce the size and the cost of the radio-frequency front end circuit.

### Second Embodiment

The radio-frequency front end circuit in which the pass band and the attenuation band are varied for the filter 21 and the pass band and the attenuation band are fixed for the filter 22 is exemplified in the first embodiment. In contrast, a radio-frequency front end circuit in which the pass band and the attenuation band are varied for two filters is exemplified in the present embodiment. As for the radio-frequency front end circuit according to the present embodiment, a description of the same points as in the radio-frequency front end circuit according to the first embodiment is omitted herein and points different from those in the radio-frequency front end circuit according to the first embodiment will be mainly described.

### [2. 1 Circuit Configuration of Communication Apparatus]

FIG. 11 is a configuration diagram of a radio-frequency front end circuit 8 according to a second embodiment and circuits around the radio-frequency front end circuit 8. The antenna element 1, the radio-frequency front end circuit 8, the transmission amplifier circuit 3A, the reception amplifier circuit 3B, and the RFIC 4 are illustrated in FIG. 11. The radio-frequency front end circuit 8, the transmission amplifier circuit 3A, the reception amplifier circuit 3B, and RFIC 4 compose a communication apparatus. The antenna element 1, the radio-frequency front end circuit 8, the transmission amplifier circuit 3A, the reception amplifier circuit 3B, and RFIC 4 are disposed in, for example, a front end unit in a multimode-multiband cellular phone.

### [2. 2 Configuration of Radio-Frequency Front End Circuit]

The radio-frequency front end circuit 8 includes filters 81 and 82, switches 83, 84, 85, and 86, the antenna common terminal 110, the transmission terminal 120, and the reception terminal 130. With this configuration, the radio-frequency front end circuit 8 transmits and receives radio-frequency signals in BandC (the first band) and BandD (the second band) via the antenna element 1.

The filter 81 is the first filter which includes the first input-output terminal (not illustrated) connected to the antenna common terminal 110 and the second input-output terminal (not illustrated) connected to the switch 83 and the frequencies of the pass band of which are varied between the first pass band and the second pass band. The first pass band corresponds to a transmission band of BandC, and the second pass band corresponds to a reception band of BandD.

The filter 82 is the second filter which includes the third input-output terminal (not illustrated) connected to the antenna common terminal 110 and the fourth input-output terminal (not illustrated) connected to the switch 84 and the frequencies of the pass band of which are varied between the third pass band and a fourth pass band. The third pass band corresponds to a reception band of BandC, and the fourth pass band corresponds to a transmission band of BandD.

The filter 81 and the filter 82 compose a duplexer corresponding to both BandC and BandD.

The switch 83 is the SPDT first switch circuit which includes a common terminal 83a (the first common terminal), a selection terminal 83b (the first selection terminal), and a selection terminal 83c (the second selection terminal) and in which connection between the common terminal 83a and the selection terminal 83b and connection between the common terminal 83a and the selection terminal 83c are exclusively switched in response to the control signal S2 from the RFIC 4. The common terminal 83a is connected to the second input-output terminal of the filter 81. The selection terminal 83b is connected to a transmission-side path including the switch 85, the transmission terminal 120, and the transmission amplifier circuit 3A. The selection terminal 83c is connected to a reception-side path including the switch 86, the reception terminal 130, and the reception amplifier circuit 3B.

The switch 84 is an SPDT switch circuit which includes a common terminal 84a and selection terminals 84b and 84c and in which connection between the common terminal 84a and the selection terminal 84b and connection between the common terminal 84a and the selection terminal 84c are exclusively switched in response to a control signal S5 from the RFIC 4. The common terminal 84a is connected to the fourth input-output terminal of the filter 82. The selection terminal 84b is connected to the reception-side path including the switch 86, the reception terminal 130, and the reception amplifier circuit 3B. The selection terminal 84c is connected to the transmission-side path including the switch 85, the transmission terminal 120, and the transmission amplifier circuit 3A.

With the above configuration, the filter 81 is capable of being used while the variable pass band of the filter 81 is switched between the transmission band of BandC and the reception band of BandD with the switch 83. The filter 82 is capable of being used while the variable pass band of the filter 82 is switched between the reception band of BandC and the transmission band of BandD with the switch 84. In other words, each of the filters 81 and 82 serves as both the transmission filter of one band and the reception filter of the other band. Accordingly, the number of filters or duplexers composed of the filters is capable of being decreased in a multiband system.

The switch 86 is the SPDT second switch circuit which includes a common terminal 86a (the second common terminal), a selection terminal 86c (the third selection terminal), and a selection terminal 86b (the fourth selection terminal) and in which connection between the common terminal 86a and the selection terminal 86b and connection between the common terminal 86a and the selection terminal 86c are exclusively switched in response to a control signal S6 from the RFIC 4. The selection terminal 86c is connected to the selection terminal 83c. The selection terminal 86b is connected to the fourth input-output terminal of the filter 82 via the switch 84 and the reception-side path. The common terminal 86a is connected to the reception-side path including the reception terminal 130 and the reception amplifier circuit 3B.

The switch 85 is an SPDT switch circuit which includes a common terminal 85a and selection terminals 85b and 85c and in which connection between the common terminal 85a and the selection terminal 85b and connection between the common terminal 85a and the selection terminal 85c are exclusively switched in response to the control signal S3 from the RFIC 4. The selection terminal 85b is connected to the selection terminal 83b. The selection terminal 85c is connected to the fourth input-output terminal of the filter 82 via the switch 84 and the transmission-side path. The common terminal 85a is connected to the transmission-side path including the transmission terminal 120 and the transmission amplifier circuit 3A.

Due to the disposition of the switches 85 and 86, for example, when the filter 81 is used as the transmission filter of BandC, the filter 82 is capable of being used as the reception filter of BandC. Alternatively, when the filter 81 is used as the reception filter of BandD, the filter 82 is capable of being used as the transmission filter of BandD. Accordingly, the number of filters or duplexers composed of the filters is capable of being decreased in a multiband system.

A case will now be described in which the radio-frequency front end circuit 8 is applied to a multiband system using Band27 and Band20 in the LTE standard.

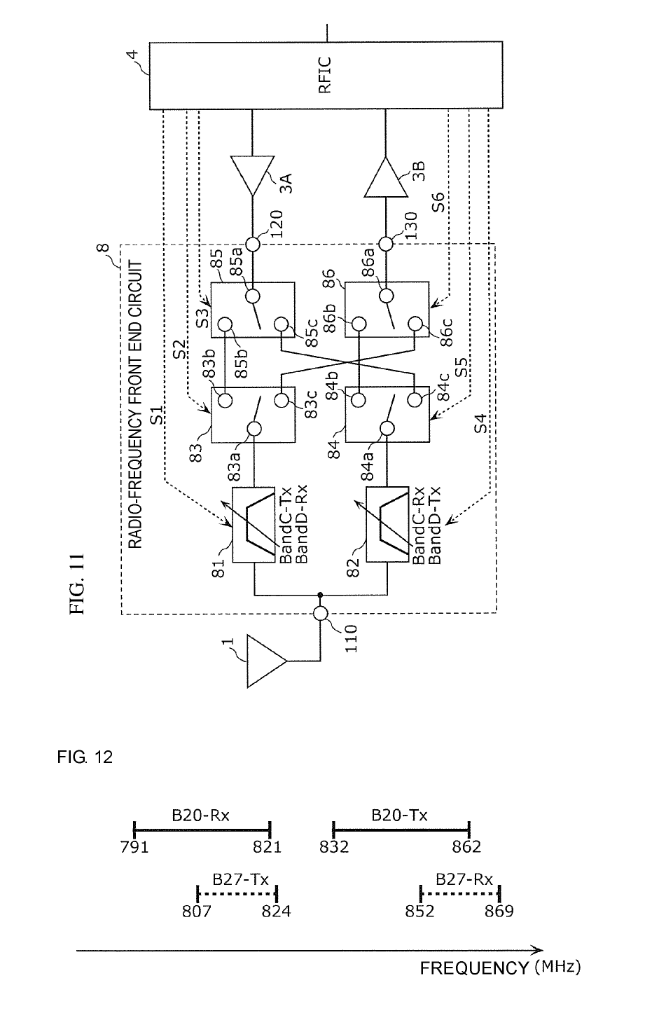

FIG. 12 is a diagram for describing frequency allocation in the bands used in the radio-frequency front end circuit 8 according to the second embodiment. The frequency allocation of Band27 and Band20 is illustrated in FIG. 12. The transmission band of Band27 (807 MHz to 824 MHz) and the reception band of Band20 (791 MHz to 821 MHz) are partially overlapped with each other. The reception band of Band27 (852 MHz to 869 MHz) and the transmission band of Band20 (832 MHz to 862 MHz) are partially overlapped with each other. Band27 and Band20 are not simultaneously used but exclusively used.

In a multiband system using the above two bands, the variable pass band of the filter 81 is associated with the transmission band of Band27 (the first band) and the reception band of Band20 (the second band), the frequency bands of which are partially overlapped with each other. The variable pass band of the filter 82 is associated with the reception band of Band27 and the transmission band of Band20, the frequency bands of which are partially overlapped with each other.

Accordingly, in the radio-frequency front end circuit 8, the common terminal 83a of the switch 83 is connected downstream of the tunable filter 81 having the variable pass band and attenuation band, as illustrated in FIG. 11, to switch between the transmission band of Band27 and the reception band of Band20. In addition, the common terminal 84a of the switch 84 is connected downstream of the tunable filter 82 having the variable pass band and attenuation band to switch between the reception band of Band27 and the transmission band of Band20. Consequently, the radio-frequency front end circuit 8 composes a duplexer circuit supporting the two bands, in which the filter 81 and the filter 82 are connected to the antenna common terminal 110. The frequency band of the filter 81 is varied between the transmission band of Band27 and the reception band of Band20. The frequency band of the filter 82 is varied between the reception band of Band27 and the transmission band of Band20. A specific circuit configuration of the filters 21 and 22 will now be described.

### [2. 3 Circuit Operation of Radio-Frequency Front End Circuit]

A circuit operation of the radio-frequency front end circuit 8 will now be described.

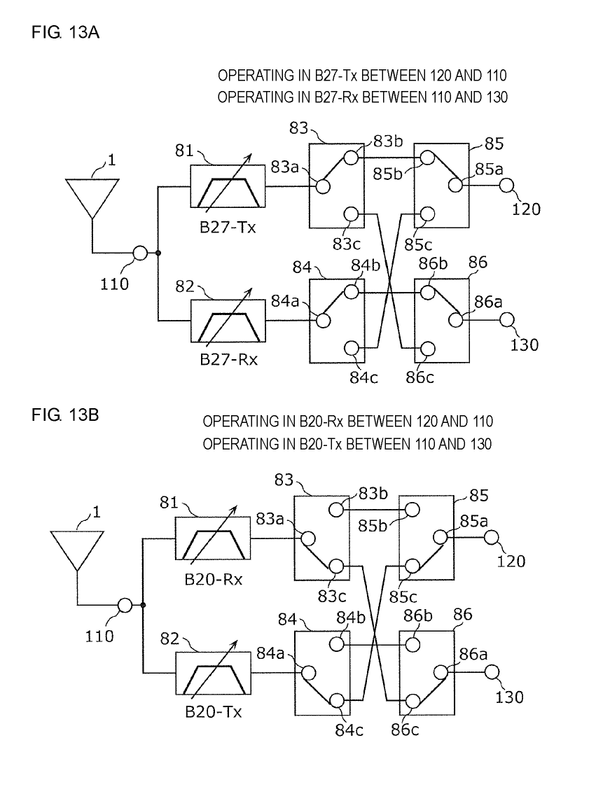

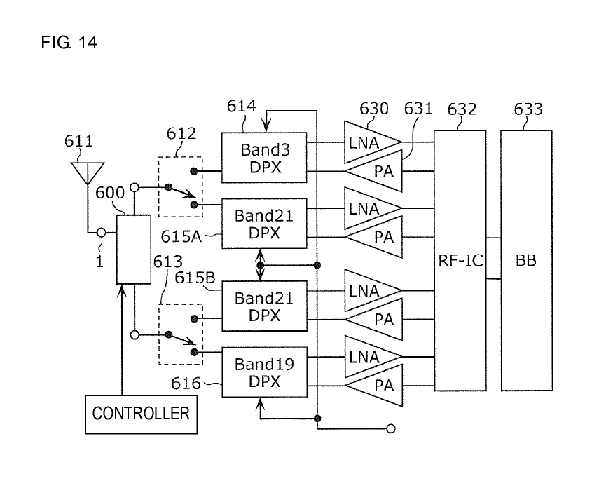

FIG. 13A is a graph indicating circuit connection of the radio-frequency front end circuit 8 according to the second embodiment in Band27 transmission and reception. FIG. 13B is a graph indicating circuit connection of the radio-frequency front end circuit 8 according to the second embodiment in Band20 transmission and reception.

First, in a mode in which Band27 is used, the radio-frequency front end circuit 8 has a circuit connection configuration illustrated in FIG. 13A. Specifically, the common terminal 83a of the switch 83 is connected to the selection terminal 83b thereof in response to the control signal S2 from the RFIC 4, and the common terminal 85a of the switch 85 is connected to the selection terminal 85b thereof in response to the control signal S3 from the RFIC 4. In other words, the filter 81 is connected to the transmission terminal 120 via the switches 83 and 85 and functions as a Band27 transmission filter. The common terminal 84a of the switch 84 is connected to the selection terminal 84b thereof in response to the control signal S5 from the RFIC 4, and the common terminal 86a of the switch 86 is connected to the selection terminal 86b thereof in response to the control signal S6 from the RFIC 4. In other words, the filter 82 is connected to the reception terminal 130 via the switches 84 and 86 and functions as a Band27 reception filter.

In addition, in the mode in which Band27 is used, the filter 81 has bandpass characteristics in which the transmission band (807 MHz to 824 MHz) of Band27 is used as the pass band and the reception band (852 MHz to 869 MHz) of Band27 is used as the attenuation band through switching between turning-on and turning-off of a switch provided in the filter 81 in response to the control signal S1 from the RFIC 4. In contrast, the filter 82 has bandpass characteristics in which the transmission band (807 MHz to 824 MHz) of Band27 is used as the attenuation band and the reception band (852 MHz to 869 MHz) of Band27 is used as the pass band through switching between turning-on and turning-off of a switch provided in the filter 82 in response to the control signal S4 from the RFIC 4.

Next, in a mode in which Band20 is used, the radio-frequency front end circuit 8 has a circuit connection configuration illustrated in FIG. 13B. Specifically, the common terminal 83a of the switch 83 is connected to the selection terminal 83c thereof in response to the control signal S2 from the RFIC 4, and the common terminal 86a of the switch 86 is connected to the selection terminal 86c thereof in response to the control signal S6 from the RFIC 4. In other words, the filter 81 is connected to the reception terminal 130 via the switches 83 and 86 and functions as a Band20 reception filter. The common terminal 84a of the switch 84 is connected to the selection terminal 84c thereof in response to the control signal S5 from the RFIC 4, and the common terminal 85a of the switch 85 is connected to the selection terminal 85c thereof in response to the control signal S3 from the RFIC 4. In other words, the filter 82 is connected to the transmission terminal 120 via the switches 84 and 85 and functions as a Band20 transmission filter.

In addition, in the mode in which Band20 is used, the filter 81 has bandpass characteristics in which the reception band (791 MHz to 821 MHz) of Band20 is used as the pass band and the transmission band (832 MHz to 862 MHz) of Band20 is used as the attenuation band through switching between turning-on and turning-off of the switch provided in the filter 81 in response to the control signal S1 from the RFIC 4. In contrast, the filter 82 has bandpass characteristics in which the reception band (791 MHz to 821 MHz) of Band20 is used as the attenuation band and the transmission band (832 MHz to 862 MHz) of Band20 is used as the pass band through switching between turning-on and turning-off of the switch provided in the filter 82 in response to the control signal S4 from the RFIC 4.

As described above, switching between the switches 83 to 86 and varying the pass bands and the attenuation bands of the filters 81 and 82 enable the filter 81 to be applied to the transmission filter of Band27 and the reception filter of Band20 and enable the filter 82 to be applied to the reception filter of Band27 and the transmission filter of Band20. Accordingly, it is possible to configure the compact multiband radio-frequency front end circuit using the two bands at a low cost.

### Other Embodiments

Although the radio-frequency front end circuits according to the first and second embodiments and the modifications of the present disclosure are described above, the radio-frequency front end circuits of the present disclosure are not limited to the above embodiments and modifications. Other embodiments realized by combining arbitrary components in the embodiments and the modifications, modifications made by making various changes supposed by the persons skilled in the art to the embodiments within the scope and sprit of the present disclosure, and various devices each incorporating any of the radio-frequency front end circuits in present disclosure are also included in the present disclosure.

In addition, the communication apparatus including the radio-frequency front end circuit, the controller that controls the pass band of each filter in conjunction with the connection state between the switch circuits, and the RFIC 4 processing a radio-frequency signal is also included in the present disclosure. Accordingly, it is possible to reduce the size and the cost of the communication apparatus.

Although the radio-frequency front end circuits according to the first and second embodiments and the modifications are described to be applied to a system that switches between frequency bands that are adjacent to each other, the radio-frequency front end circuits according to the first and second embodiments and the modifications are also capable of being applied to a system that exclusively switches between multiple channels that are allocated in one frequency band and that are adjacent to each other.

In addition, in the radio-frequency front end circuits according to the first and second embodiments and the modifications, an inductor and/or a capacitor may further be connected between the respective terminals, such as the input terminal, the output terminal, and the communication terminal.

### INDUSTRIAL APPLICABILITY

The present disclosure is capable of being widely used in a communication device, such as a cellular phone, as the radio-frequency front end circuit and the communication apparatus, which are applicable to a multiband-multimode system and which are compact and inexpensive.

### REFERENCE SIGNS LIST

1 antenna element
2, 2A, 2B, 5, 6, 8, 500 radio-frequency front end circuit
3A, 3C, 3D, 3E transmission amplifier circuit
3B, 3F, 3G, 3H reception amplifier circuit
4, 632 RF signal processing circuit (RFIC)
7 baseband signal processing circuit (BBIC)
9 communication apparatus
11a, 11b, 104 IDT electrode
21, 22, 31R, 31T, 32R, 32T, 33R, 33T, 34R, 34T, 41R, 41T, 42R, 42T, 43R, 43T, 44R, 44T, 45R, 45T, 46R, 46T, 81, 82, 528bT, 528bR, 528aT, 528aR, 529R filter
21C capacitor
21L, 22L inductor
23, 24, 27, 28, 30, 40, 50, 61, 62, 63, 64, 65, 66, 83, 84, 85, 86, 216, 217 switch
23a, 24a, 27a, 27e, 28a, 28b, 28e, 28f, 83a, 84a, 85a, 86a common terminal
23b, 23c, 24b, 24c, 27b, 27c, 27d, 28c, 28d, 83b, 83c, 84b, 84c, 85b, 85c, 86b, 86c selection terminal
70 demultiplexer
100 piezoelectric substrate
101 close contact layer
102 main electrode layer
103 protective layer
110 antenna common terminal
110a, 110b electrode finger
111a, 111b busbar electrode
120 transmission terminal
130 reception terminal
211s, 212s, 213s, 214s, 221s, 222s, 223s series arm resonator
221p, 222p, 223p, 224p, 225p parallel arm resonator
224 longitudinally coupled resonator type filter unit
521, 523 SP3T switch
522, 612, 613 SPDT switch
600 tunable diplexer
611 antenna
614, 615A, 615B, 616 duplexer
630 low noise amplifier
631 power amplifier
633 baseband signal processing circuit

1. A radio-frequency front end circuit having a common antenna terminal configured to connect to an antenna and for transmitting and receiving radio-frequency signals, the radio-frequency front end circuit comprising:
a first filter having a first input-output terminal and a second input-output terminal, wherein the first input-output terminal is connected to the common antenna terminal, and a pass band of the first filter is variable between frequencies of a first pass band and frequencies of a second pass band;
a second filter having a third input-output terminal and a fourth input-output terminal, wherein the third input-output terminal is connected to the common antenna terminal, and a pass band of the second filter corresponds to frequencies of a third pass band, the frequencies of the third pass band not overlapping with the frequencies of the first pass band or the frequencies of the second pass band; and
a first switch circuit having a first common terminal, a first selection terminal, and a second selection terminal, wherein the first common terminal is connected to the second input-output terminal, and the first switch circuit is configured to selectively switch the first common terminal exclusively between the first selection terminal and the second selection terminal.

2. The radio-frequency front end circuit according to claim 1, further comprising:
a transmission terminal through which a transmission radio-frequency signal from a subsequent circuit is input;
a reception terminal through which a reception radio-frequency signal is supplied to the subsequent circuit; and
a second switch circuit having a second common terminal, a third selection terminal, and a fourth selection terminal, wherein the third selection terminal is connected to the second selection terminal, the fourth selection terminal is connected to the fourth input-output terminal, and the second common terminal is connected to the reception terminal or the transmission terminal,
wherein the first selection terminal is connected to the other of the reception terminal or the transmission terminal.

3. The radio-frequency front end circuit according to claim 1, wherein the first switch circuit is a single pole double throw switch.

4. The radio-frequency front end circuit according to claim 1, wherein the first switch circuit and the second switch circuit are formed in one package.

5. The radio-frequency front end circuit according to claim 1,
wherein the radio-frequency front end circuit is configured to transmit and receive: first radio-frequency signals in a first band in which the first pass band is a transmission band and the third pass band is a reception band, and second radio-frequency signals in a second band in which the second pass band is the reception band and which is used exclusively with the first band, and
wherein the first pass band and the second pass band at least partially overlap.

6. The radio-frequency front end circuit according to claim 5,
wherein the first band is Band28b (transmission band: 718 MHz to 748 MHz and reception band: 773 MHz to 803 MHz) in a Long Term Evolution standard, the second band is Band29 (reception band: 717.25 MHz to 727.25 MHz) in the Long Term Evolution standard,
and wherein the radio-frequency front end circuit is further configured to transmit and receive third radio-frequency signals in a third band, the third band being Band28a (transmission band: 703 MHz to 733 MHz and reception band: 758 MHz to 788 MHz) in the Long Term Evolution standard.

7. The radio-frequency front end circuit according to claim 5, wherein the first band is Band27 (transmission band: 807 MHz to 824 MHz and reception band: 852 MHz to 869 MHz) in a Long Term Evolution standard, and the second band is Band20 (transmission band: 832 MHz to 862 MHz and reception band: 791 MHz to 821 MHz) in the Long Term Evolution standard.

8. The radio-frequency front end circuit according to claim 1,
wherein the first filter comprises:
a series arm resonator connected on a path between the first input-output terminal and the second input-output terminal;
a parallel arm resonator connected between a node on the path, and a reference terminal; and
a switch disposed between the node and the reference terminal, the switch being configured to selectively connect the parallel arm resonator to the reference terminal.

9. The radio-frequency front end circuit according to claim 1, wherein each of the first filter and the second filter is a surface acoustic wave filter, an acoustic wave filter using bulk acoustic waves (BAWs), an LC resonant filter, or a dielectric filter.

10. The radio-frequency front end circuit according to claim 1, wherein the switch is a field effect transistor switch made of gallium arsenide (GaAs), is formed of a complementary metal oxide semiconductor, or is a diode switch.

11. The radio-frequency front end circuit according to claim 1, further comprising:
a transmission amplifier circuit that is connected to the first selection terminal or the second selection terminal, and that is configured to amplify a radio-frequency transmission signal; and
a reception amplifier circuit that is connected to the other of the first selection terminal or the second selection terminal, and that is configured to amplify a radio-frequency reception signal.

12. A communication apparatus comprising:
the radio-frequency front end circuit according to claim 1;
a controller configured to control the pass band of the first filter and a connection state of the first switch circuit; and
a radio-frequency signal processing circuit configured to process the radio-frequency signals,
wherein the controller is configured to vary the pass band of the first filter between the first pass band and the second pass band in conjunction with switching connection of the first common terminal between the first selection terminal and the second selection terminal.
